(19) United States
(12) Patent Application Publication
(10) Pub. No.: US 2017/0104036 A1
(43) Pub. Date: Apr. 13, 2017

(54) DISPLAY DEVICE

(71) Applicant: Japan Display Inc., Minato-ku (JP)

(72) Inventor: Norihisa MAEDA, Minato-ku (JP)

(73) Assignee: Japan Display Inc., Minato-ku (JP)

(21) Appl. No.: 15/275,960

(22) Filed: Sep. 26, 2016

(30) Foreign Application Priority Data
Oct. 9, 2015 (JP) 2015-201549

(51) Int. Cl. H01L 27/32; H01L 51/52

(52) U.S. Cl. CPC H01L 27/3211; H01L 27/322; H01L 51/5262

(57) ABSTRACT

A display device includes a plurality of pixel electrodes that correspond to the plurality of unit pixels, respectively, and are formed of a plurality of groups defined for the plurality of colors, a self-light emitting element layer, a common electrode, a plurality of optical path length adjusting layers, and a semi-light transmitting film that is laminated so as to be electrically connected to the common electrode and is conductive and has both of light transmission characteristics and light reflection characteristics. The plurality of optical path length adjusting layers having different thicknesses depending on which of the plurality of groups each of the plurality of optical path length adjusting layers belongs to. The display device having a microcavity structure formed such that light having a wavelength corresponding to each of the thicknesses resonates between corresponding one of the plurality of pixel electrodes and the semi-light transmitting film.

### CROSS-REFERENCE TO RELATED APPLICATION

The present application claims priority from the Japanese Application JP2015-201549. The Japanese Application JP2015-201549 is incorporated by reference into this application.

### BACKGROUND OF THE INVENTION

1. Field of the Invention

The present invention relates to a display device.

2. Description of the Related Art

In recent years, needs for slim display devices have been increased along with informatization development. Slim display devices such as liquid crystal display devices, plasma displays, and organic electro luminescence (EL) display devices have been put to practical use. In addition, research and development for increasing luminance and resolution of each type of slim display devices has been actively conducted.

For example, one proposed method for increasing luminance of organic EL display devices includes employing microcavity structures in organic EL display devices having top emission type light emitting element structures. In the organic EL element having the top emission type light emitting element structure, a cathode electrode provided on an upper layer of the organic EL element is required to have optical transparency, and indium tin oxide (ITO), indium zinc oxide (IZO), or the like is used for the cathode electrode. However, ITO, IZO, and the like have high electric resistance, and hence there is a fear in that as the area of the display device is increased, in-plane electric resistance becomes uneven to cause luminance unevenness.

Further, the organic EL element employing the microcavity structure may strengthen the intensity at a certain wavelength by repeatedly reflecting light generated from a light emitting layer between a reflective electrode and a semi-light transmitting film, and emitting only light having a matched wavelength (see Japanese Patent Application Laid-open No. 2008-218081). Thus, the design of optical path lengths is important in the microcavity structures. In organic EL display devices configured to perform color display, it is particularly important to adjust optical path lengths for respective colors.

As a technology for adjusting optical path lengths and reducing resistance of cathode electrodes as described above, for example, in Japanese Patent Application Laid-open No. 2009-272150, it is disclosed that optical path length adjusting layers, which have different thicknesses depending on colors of pixels, are formed on an ITO cathode, an inorganic protective film is formed as an upper layer of the optical path length adjusting layers, and a semi-transmissive reflective film is formed as an upper layer of the inorganic protective film.

### SUMMARY OF THE INVENTION

When a configuration including auxiliary wiring formed above a partition wall is adopted as in Japanese Patent Application Laid-open No. 2009-272150, it is necessary to form a new layer, namely, auxiliary wiring, and hence the structure is complicated. Thus, a load on a manufacturing process of this configuration is large, resulting in a difficulty in achieving higher resolution. The present invention has been made in view of the above-mentioned problems, and has an object to provide a display device that is manufactured with a reduced load and is configured to prevent luminance unevenness from occurring and to individually adjust the thicknesses of optical path length adjusting layers depending on colors of pixels, thereby increasing luminance of the display device.

According to one aspect of the present invention, a display device, which is configured to display a color image formed of a plurality of unit pixels of a plurality of colors. The display device includes a plurality of pixel electrodes that correspond to the plurality of unit pixels, respectively, and are formed of a plurality of groups defined for the plurality of colors, a self-light emitting element layer that is laminated on the plurality of pixel electrodes, and is configured to emit light with current, a common electrode that is laminated on the self-light emitting element layer and has optical transparency, a plurality of optical path length adjusting layers that have optical transparency, and are laminated on the common electrode at least above the plurality of pixel electrodes that are independent of one of the plurality of groups and belong to the remaining groups, and a semi-light transmitting film that is laminated on the plurality of optical path length adjusting layers and is laminated so as to be electrically connected to the common electrode, and is conductive and has both of light transmission characteristics and light reflection characteristics. The plurality of optical path length adjusting layers having different thicknesses depending on which of the plurality of groups each of the plurality of optical path length adjusting layers belongs to. The display device having a microcavity structure formed such that light having a wavelength corresponding to each of the thicknesses resonates between corresponding one of the plurality of pixel electrodes and the semi-light transmitting film.

In one embodiment of the present invention, the plurality of optical path length adjusting layers are formed above all of the plurality of pixel electrodes.

In one embodiment of the present invention, the plurality of optical path length adjusting layers are prevented from being formed above, among the plurality of pixel electrodes, a pixel electrode belonging to the one of the plurality of groups, and are formed above the plurality of pixel electrodes belonging to the remaining groups.

In one embodiment of the present invention, the display device further includes an insulating layer covering a peripheral portion of each of the plurality of pixel electrodes. The common electrode is formed above the insulating layer. The plurality of optical path length adjusting layers are formed except for at least above an upper end surface of the insulating layer. The semi-light transmitting film is electrically connected to the common electrode above the upper end surface of the insulating layer while overlapping with the common electrode.

In one embodiment of the present invention, the display device further includes a color filter having coloring regions of the plurality of colors above the semi-light transmitting film. The self-light emitting element layer is configured to emit light of a single color. The light that is to resonate in the microcavity structure comprises light having a wavelength being allowed to transmit through the coloring regions that the light having transmitted through the semi-light transmitting film reaches.

In one embodiment of the present invention, the self-light emitting element layer comprises a plurality of groups of self-light emitting element layers configured to emit light of the plurality of colors, respectively. The light that is to resonate in the microcavity structure comprises light emitted from each of the plurality of groups of the self-light emitting element layers.

In one embodiment of the present invention, the plurality of optical path length adjusting layers are made of resin.

In one embodiment of the present invention, the semi-light transmitting film is made of one of magnesium silver and silver.

### BRIEF DESCRIPTION OF THE DRAWINGS

FIG. 1 is a view for schematically illustrating a display device according to an embodiment of the present invention.

FIG. 2 is a view for illustrating the configuration of an organic EL panel when viewed from a display side thereof.

FIG. 3 is a sectional view taken along the line of FIG. 2.

FIG. 4 is an enlarged sectional view taken along the line IV-IV of FIG. 3.

FIG. 5 is a view for illustrating an embodiment of the present invention in which optical path length adjusting layers are formed only above a part of pixel electrodes.

FIG. 6 is a view for illustrating an embodiment of the present invention in which self-white light emitting element layers are used.

FIG. 7 is a view for illustrating an embodiment of the present invention in which first and second common layers are formed only above the pixel electrodes.

### DETAILED DESCRIPTION OF THE INVENTION

Embodiments of the present invention are described below with reference to the attached drawings. The disclosure is only exemplary, and modifications made as appropriate within the gist of the present invention that can be conceived with ease by those skilled in the art are naturally within the scope of the present invention. For clearer illustration, some widths, thicknesses, shapes, and the like of respective portions are schematically illustrated in the drawings in comparison to actual ones. However, the widths, the thicknesses, the shapes, and the like are merely an example, and do not limit understanding of the present invention. Further, like elements as those described relating to the drawings already referred to are denoted by like reference symbols herein and in each of the drawings, and detailed description thereof is sometimes omitted as appropriate.

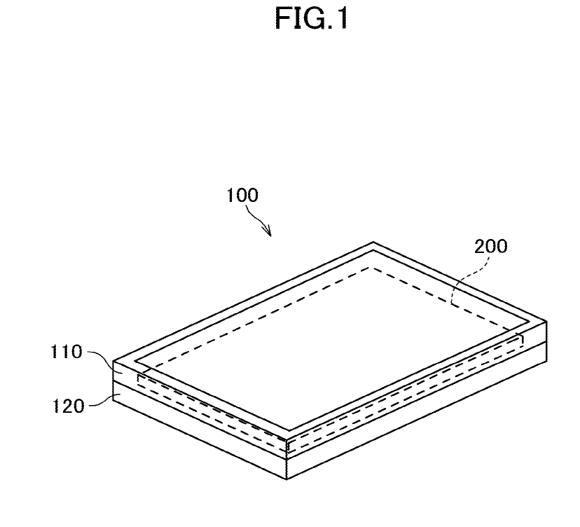

FIG. 1 is a view for schematically illustrating a display device 100 according to an embodiment of the present invention. As illustrated in FIG. 1, the display device 100 includes an organic EL panel 200 sandwiched and fixed between an upper frame 110 and a lower frame 120.

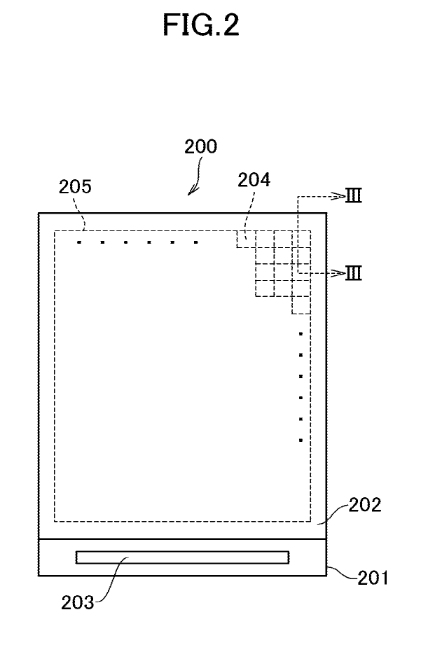

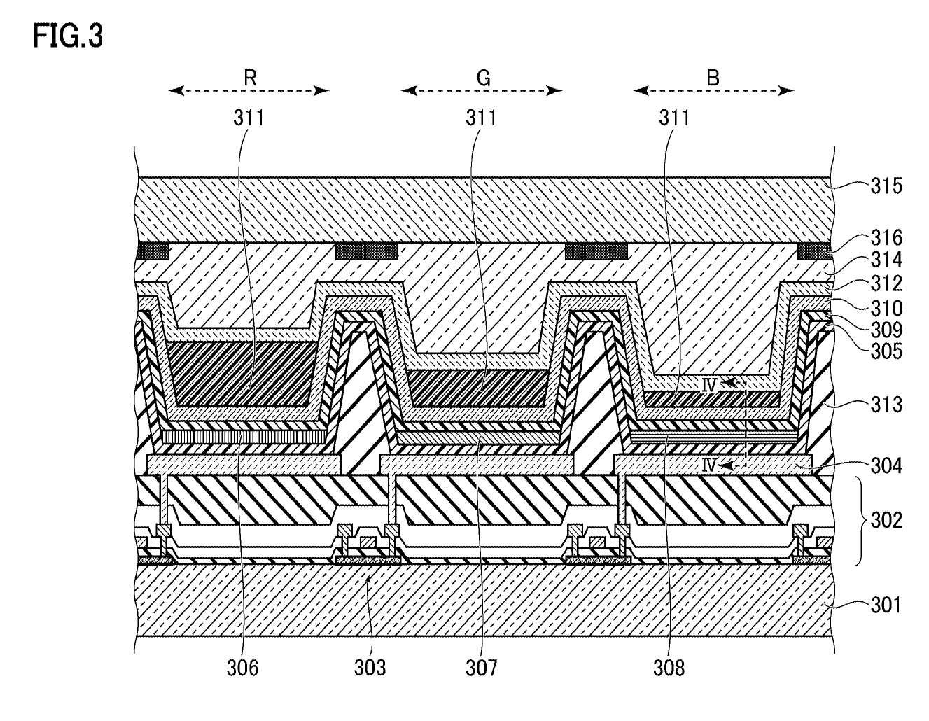

FIG. 2 is a schematic view for illustrating the configuration of the organic EL panel 200 of FIG. 1. As illustrated in FIG. 2, the organic EL panel 200 includes an array substrate 201, an opposing substrate 202, and a driver integrated circuit (IC) 203. The array substrate 201 has formed therein self-light emitting element layers described later, and is bonded to the opposing substrate 202 with a filler 314 (see FIG. 3). The driver IC 203 is configured to, for example, apply a potential to scanning signal lines of pixel transistors 303, which are arranged for respective unit pixels 204 corresponding to a plurality of subpixels forming one pixel for full color display, thereby electrically connecting a source and a drain of each of the pixel transistors 303, and to cause current corresponding to grayscale values of the unit pixels 204 to flow to data signal lines of the respective pixel transistors 303. The organic EL panel 200 is configured to display a color image formed of the plurality of unit pixels 204 of a plurality of colors on a display region 205 with the driver IC 203.

Subsequently, the sectional structure of the organic EL panel 200 is described. FIG. 3 is a sectional view taken along the line of FIG. 2. As illustrated in FIG. 3, the array substrate 201 includes a lower glass substrate 301, and a thin film transistor (TFT) circuit layer 302, a plurality of pixel electrodes 304, self-light emitting element layers 305 to 309, a common electrode 310, a plurality of optical path length adjusting layers 311, and a semi-light transmitting film 312 that are formed on the lower glass substrate 301 in the stated order toward the opposing substrate 202. Further, the opposing substrate 202 includes an upper glass substrate 315 and a light shielding film 316 formed on the upper glass substrate 315. In addition, a space between the array substrate 201 and the opposing substrate 202 is filled with the filler 314.

The TFT circuit layer 302 includes the pixel transistors 303 each including source wiring, drain wiring, gate wiring, and a semiconductor layer. One of the source wiring and the drain wiring of the pixel transistor 303 is connected to the pixel electrode 304. The detailed structure of the pixel transistors 303 is similar to that in the related art, and hence description thereof is omitted.

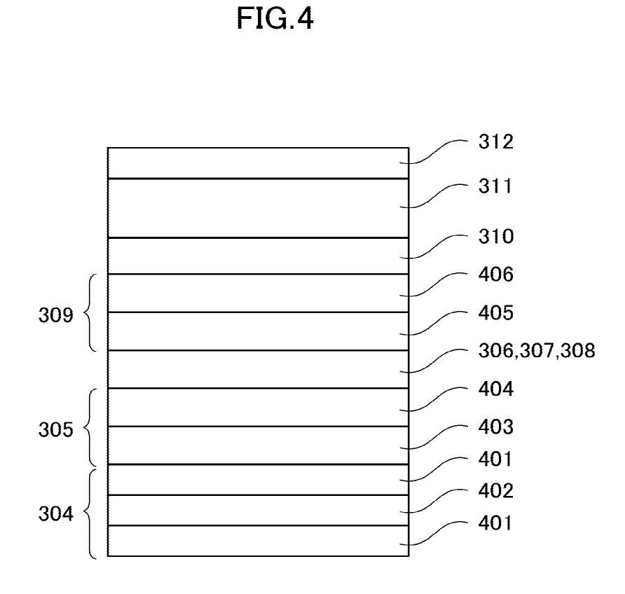

The plurality of pixel electrodes 304 correspond to the plurality of unit pixels 204, respectively, and are formed of a plurality of groups defined for a plurality of colors. Specifically, for example, the plurality of pixel electrodes 304 are divided into three groups of a group having formed therein a red light emitting layer 306 configured to emit red light, a group having formed therein a green light emitting layer 307 configured to emit green light, and a group having formed therein a blue light emitting layer 308 configured to emit blue light. Further, the pixel electrodes 304 correspond to the three-color unit pixels 204, respectively. That is, the pixel electrodes 304 correspond to the three-color unit pixels 204, respectively, and are formed of the three groups defined for the three colors. Further, FIG. 4 is an enlarged sectional view taken along the line IV-IV of FIG. 3. As illustrated in FIG. 4, the pixel electrodes 304 are each formed of an ITO layer 401, a Ag layer 402, and an ITO layer 401 that are laminated in the stated order.

The self-light emitting element layers 305 to 309 are laminated on the plurality of pixel electrodes 304, and are configured to emit light with current for controlling luminance of the self-light emitting element layers 305 to 309. Further, the self-light emitting element layers 305 to 309 include a first common layer 305, a second common layer 309, and a plurality of groups of light emitting layers configured to emit light of the plurality of colors, respectively. Specifically, for example, as illustrated in FIG. 3, the first common layer 305 is formed on the upper layer side of the pixel electrodes 304 and an insulating layer 313 over the entire display region 205.

Further, from the upper left side of the drawing sheet, the red light emitting layer 306, the green light emitting layer 307, and the blue light emitting layer 308 are formed above the pixel electrodes 304 and on the upper layer side of the first common layer 305, thereby forming the light emitting layers of the three groups. In addition, the second common layer 309 is formed on the upper layer side of the first common layer 305 and the light emitting layers 306, 307, and 308 over the entire display region 205.

More specifically, as illustrated in FIG. 4, the self-light emitting element layers 305 to 309 are formed of a hole injection layer 403, a hole transport layer 404, the light emitting layers 306, 307, and 308, an electron transport layer 405, and an electron injection layer 406 that are laminated on the upper layer side of the pixel electrodes 304 and the insulating layer 313 in the stated order. That is, the first common layer 305 of FIG. 3 corresponds to the hole injection layer 403 and the hole transport layer 404 of FIG. 4, and the second common layer 309 of FIG. 3 corresponds to the electron transport layer 405 and the electron injection layer 406 of FIG. 4. Here, the light emitting layers 306, 307, and 308 are made of organic EL materials that correspond to the red light emitting layer 306, the green light emitting layer 307, and the blue light emitting layer 308, respectively. The details of the hole injection layer 403, the hole transport layer 404, the electron transport layer 405, and the electron injection layer 406 are similar to those in the related art, and hence description thereof is omitted.

A case is described above in which the three unit pixels 204 formed of the unit pixel 204 corresponding to the red light emitting layer 306, the unit pixel 204 corresponding to the green light emitting layer 307, and the unit pixel 204 corresponding to the blue light emitting layer 308 form one pixel. However, the present invention is not limited thereto. For example, four unit pixels 204 having formed therein light emitting layers configured to emit light of four colors of red, green, blue, and white may form one pixel. Further, the number of unit pixels 204 forming one pixel may be four or more.

The common electrode 310 is laminated on the self-light emitting element layers 305 to 309, and has optical transparency. The common electrode 310 is configured to cause current to flow to the light emitting layers 306, 307, and 308 together with the plurality of pixel electrodes 304. Specifically, for example, as illustrated in FIG. 3 and FIG. 4, the common electrode 310 is laminated on the upper layer side of the self-light emitting element layers 305 to 309. Further, the common electrode 310 is made of a material having conductivity and optical transparency, e.g., ITO. In addition, the common electrode 310 is formed on the upper layer side of the insulating layer 313, and is electrically connected to the semi-light transmitting film 312 above the insulating layer 313.

The plurality of optical path length adjusting layers 311 have optical transparency, and are laminated on the common electrode 310 at least above the plurality of pixel electrodes 304 that are independent of one of the plurality of groups and belong to the remaining groups. Specifically, for example, as illustrated in FIG. 3 and FIG. 4, the plurality of optical path length adjusting layers 311 are laminated on the common electrode 310 above all of the plurality of pixel electrodes 304. The optical path length adjusting layers 311 are made of transparent resin materials in order to transmit therethrough light emitted from the red light emitting layer 306, the green light emitting layer 307, and the blue light emitting layer 308, respectively.

Further, the plurality of optical path length adjusting layers 311 have different thicknesses depending on which group the optical path length adjusting layer 311 belongs to. Specifically, for example, as illustrated in FIG. 3, the optical path length adjusting layer 311 formed above the red light emitting layer 306 is thickest, whereas the optical path length adjusting layer 311 formed above the blue light emitting layer 308 is thinnest. With this configuration, such a microcavity structure is formed that light having a wavelength corresponding to the thickness of the optical path length adjusting layer 311 resonates between corresponding one of the plurality of pixel electrodes 304 and the semi-light transmitting film 312. That is, light of the respective colors emitted from the light emitting layers 306, 307, and 308 is repeatedly reflected between the pixel electrodes 304 being reflective electrodes and the semi-light transmitting film 312 being a semi-reflective electrode. Here, distances between the pixel electrodes 304 and the semi-light transmitting film 312 are adjusted by changing the thicknesses of the optical path length adjusting layers 311 depending on wavelengths of light emitted from the self-light emitting element layers. In this manner, light of the respective colors resonates, thereby enabling the intensity of light of the respective colors to be increased.

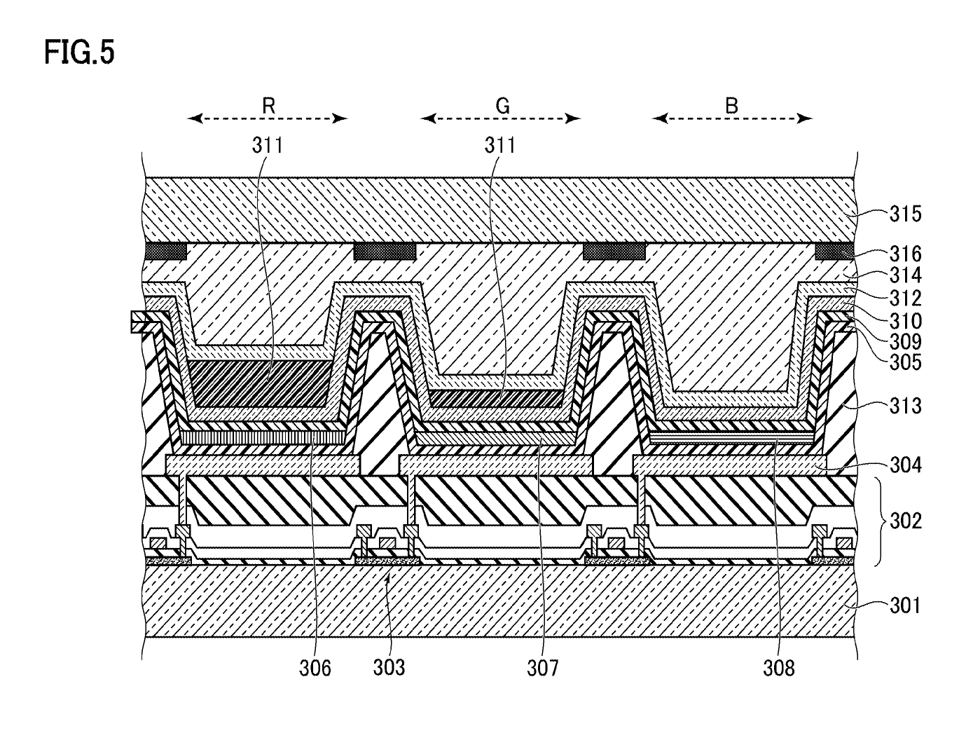

The optical path length adjusting layers 311 may be prevented from being formed above, among the plurality of pixel electrodes 304, the pixel electrode 304 belonging to one of the plurality of groups, and may be formed above the pixel electrodes 304 belonging to the remaining groups. Specifically, for example, as illustrated in FIG. 5, among the optical path length adjusting layers 311 formed above the self-light emitting element layers configured to emit light of the respective colors, the thinnest optical path length adjusting layer 311 may become unnecessary by adjusting the distance between the pixel electrode 304 and the semi-light transmitting film 312. That is, the thicknesses of the hole injection layer 403, the ITO 401, and the like formed on the lower layer side of the blue light emitting layer 308, and the thickness of the common electrode 310 formed on the upper layer side of the blue light emitting layer 308 may be adjusted so that light having a wavelength of blue may resonate. In this case, the optical path length adjusting layers 311 are formed only above the red light emitting layer 306 and the green light emitting layer 307.

Further, it is desired that the optical path length adjusting layers 311 be formed using an ink-jet method. When the optical path length adjusting layers 311 are formed using the ink-jet method, the thicknesses of the optical path length adjusting layers 311, which are formed as the upper layers of the light emitting layers 306, 307, and 308 configured to emit light of the respective colors, may be adjusted separately.

In addition, the optical path length adjusting layers 311 are formed on the common electrode 310 except for at least above the upper end surface of the insulating layer 313. No optical path length adjusting layer 311 is formed above the upper end surface of the insulating layer 313, and hence the common electrode 310 is electrically connected to the semi-light transmitting film 312 above the insulating layer 313.

The semi-light transmitting film 312 is laminated on the plurality of optical path length adjusting layers 311, and is laminated so as to be electrically connected to the common electrode 310 at least above regions around the plurality of pixel electrodes 304. Specifically, for example, as illustrated in FIG. 3, the semi-light transmitting film 312 is formed on the optical path length adjusting layers 311 in the regions above the pixel electrodes 304, and is formed on the common electrode 310 in the region above the insulating layer 313. The semi-light transmitting film 312 is in contact with the common electrode 310 in the region above the insulating layer 313, thereby being electrically connected to the common electrode 310. The common electrode 310 being in contact with the semi-light transmitting film 312 maybe equivalent to the common electrode 310 having reduced electric resistance, and hence current flowing through the common electrode 310 in the plane of the display device 100 may be prevented from becoming uneven.

It is desired that the semi-light transmitting film 312 be electrically connected to the common electrode 310 above the upper end surface of the insulating layer 313 while overlapping with the common electrode 310. As the contact area between the semi-light transmitting film 312 and the common electrode 310 becomes larger, the effect equivalent to reducing electric resistance of the common electrode 310 is increased, and current flowing through the common electrode 310 may be more uniformed.

Further, the semi-light transmitting film 312 is made of a conductive material having both of light transmission characteristics and light reflection characteristics. Specifically, for example, the semi-light transmitting film 312 is made of magnesium silver. Further, the semi-light transmitting film 312 may be made of silver.

The insulating layer 313 is formed so as to cover the peripheral portion of each of the plurality of pixel electrodes 304. Specifically, for example, as illustrated in FIG. 3, the insulating layer 313 is formed of a resin material between the pixel electrodes 304 and on the end portion of each of the pixel electrodes 304. The insulating layer 313 may prevent short-circuit between the pixel electrodes 304 and the common electrode 310.

As described above, in this embodiment, a layer formed for uniforming current flowing through the common electrode 310 and a semi-transmissive and semi-reflective layer used in the microcavity structure are shared. As a result, increase in luminance, prevention of luminance unevenness, and reduction in manufacturing load may be achieved.

The present invention is not limited to the above-mentioned embodiment, and may include various modifications. Specifically, for example, a case is described in the above-mentioned embodiment in which the self-light emitting element layers configured to emit light of different colors are formed in the respective unit pixels 204, but the present invention is not limited thereto.

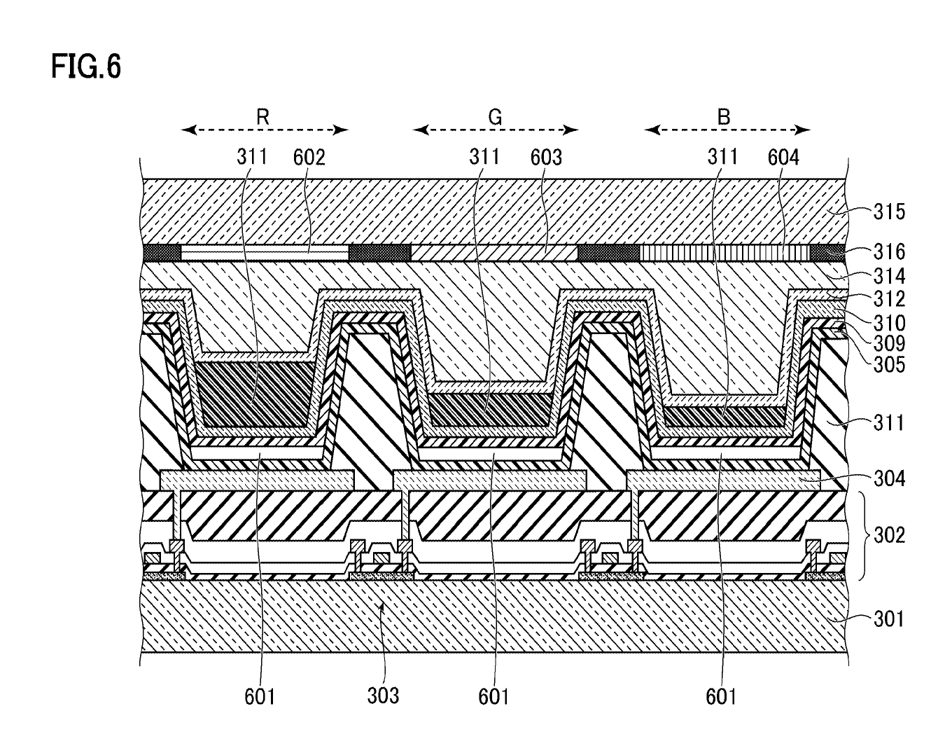

For example, the self-light emitting element layers 305 to 309 may be configured to emit light of a single color. Specifically, as illustrated in FIG. 6, all of the light emitting layers 306, 307, and 308 of FIG. 3 may be white light emitting layers 601 configured to emit white light. In this case, a material used for the light emitting layers is an organic EL material that emits white light. Further, in this case, a color filter for performing color display is formed in the opposing substrate 202.

The color filter has coloring regions of the plurality of colors above the semi-light transmitting film 312. Specifically, for example, the color filter includes, in spaces of the light shielding film 316 formed on the upper glass substrate 315, a red color filter 602 configured to selectively transmit red light therethrough, a green color filter 603 configured to selectively transmit green light therethrough, and a blue color filter 604 configured to selectively transmit blue light therethrough. Here, light that is to resonate in the microcavity structure is light having a wavelength being allowed to transmit through the color filter that the light having transmitted through the semi-light transmitting film 312 reaches. With this configuration, the display device 100 performs color display similarly to the case in which the self-light emitting element layers 305 to 309 are formed of the light emitting layers 306, 307, and 308 configured to emit light of the plurality of colors. When the self-light emitting element layers 305 to 309 are configured to emit light of a single color, the manufacturing load may further be reduced.

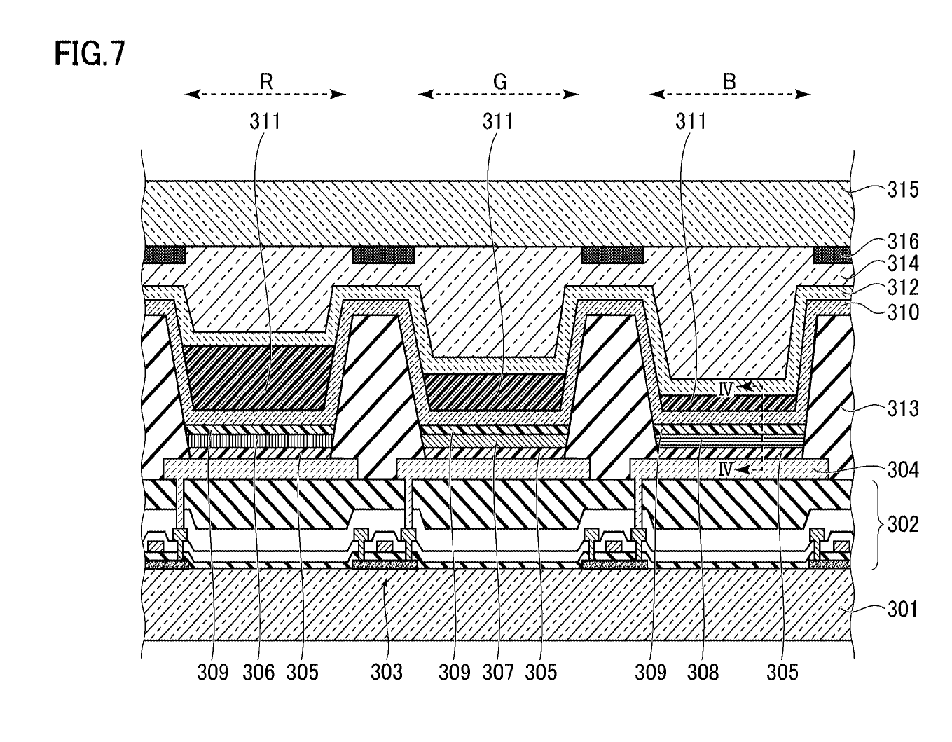

Further, a case is described above in which the first common layer 305 and the second common layer 309 are formed above the insulating layer 313, but the present invention is not limited thereto. Specifically, for example, as illustrated in FIG. 7, the first common layer 305 and the second common layer 309 included in the self-light emitting element layers 305 to 309 may only be formed in regions above the pixel electrodes 304. Even in an example illustrated in FIG. 7, the common electrode 310 and the semi-light transmitting film 312 are electrically connected to each other in the region above the insulating layer 313. Consequently, similarly to the case described above, current flowing through the common electrode 310 may be uniformed.

Those skilled in the art can conceive various modifications and variations within the scope of the idea of the present invention, and it is understood that those modifications and variations also fall within the scope of the present invention. For example, when a structural element is added to or deleted from, or a design change is made to, or, when a step is added to or deleted from, or a condition change is made to the embodiment described above as appropriate by those skilled in the art, insofar as such modifications and variations are within the gist of the present invention, such modifications and variations fall within the scope of the present invention.

What is claimed is:

1. A display device, which is configured to display a color image formed of a plurality of unit pixels of a plurality of colors, the display device comprising:
a plurality of pixel electrodes that correspond to the plurality of unit pixels, respectively, and are formed of a plurality of groups defined for the plurality of colors;
a self-light emitting element layer that is laminated on the plurality of pixel electrodes, and is configured to emit light with current;
a common electrode that is laminated on the self-light emitting element layer and has optical transparency;
a plurality of optical path length adjusting layers that have optical transparency, and are laminated on the common electrode at least above the plurality of pixel electrodes that are independent of one of the plurality of groups and belong to the remaining groups; and
a semi-light transmitting film that is laminated on the plurality of optical path length adjusting layers and is laminated so as to be electrically connected to the common electrode, and is conductive and has both of light transmission characteristics and light reflection characteristics;
the plurality of optical path length adjusting layers having different thicknesses depending on which of the plurality of groups each of the plurality of optical path length adjusting layers belongs to,
the display device having a microcavity structure formed such that light having a wavelength corresponding to each of the thicknesses resonates between corresponding one of the plurality of pixel electrodes and the semi-light transmitting film.

2. The display device according to claim 1, wherein the plurality of optical path length adjusting layers are formed above all of the plurality of pixel electrodes.

3. The display device according to claim 1, wherein the plurality of optical path length adjusting layers are prevented from being formed above, among the plurality of pixel electrodes, a pixel electrode belonging to the one of the plurality of groups, and are formed above the plurality of pixel electrodes belonging to the remaining groups.

4. The display device according to claim 1, further comprising an insulating layer covering a peripheral portion of each of the plurality of pixel electrodes,
wherein the common electrode is formed above the insulating layer,
wherein the plurality of optical path length adjusting layers are formed except for at least above an upper end surface of the insulating layer, and
wherein the semi-light transmitting film is electrically connected to the common electrode above the upper end surface of the insulating layer while overlapping with the common electrode.

5. The display device according to claim 1, further comprising a color filter having coloring regions of the plurality of colors above the semi-light transmitting film,
wherein the self-light emitting element layer is configured to emit light of a single color, and
wherein the light that is to resonate in the microcavity structure comprises light having a wavelength being allowed to transmit through the coloring regions that the light having transmitted through the semi-light transmitting film reaches.

6. The display device according to claim 1,
wherein the self-light emitting element layer comprises a plurality of groups of self-light emitting element layers configured to emit light of the plurality of colors, respectively, and
wherein the light that is to resonate in the microcavity structure comprises light emitted from each of the plurality of groups of the self-light emitting element layers.

7. The display device according to claim 1, wherein the plurality of optical path length adjusting layers are made of resin.

8. The display device according to claim 1, wherein the semi-light transmitting film is made of one of magnesium silver and silver.
